(19) United States
(12) Patent Application Publication
(10) Pub. No.: US 2003/0099099 A1
(43) Pub. Date: May 29, 2003

(54) Printed wiring board having connecting terminals for electrically connecting conductor layers, circuit module having printed wiring board, and manufacturing method for printed wiring board

(76) Inventor: Kenji Aoki, Kunitachi-shi (JP)

Correspondence Address: Finnegan, Henderson, Farabow,, Garrett & Dunner, L.L.P., 1300 I Street, N.W., Washington, DC, 20005-3315, US

(21) Appl. No.: 10/234,388

(22) Filed: Sep. 5, 2002

(30) Foreign Application Priority Data
Nov. 27, 2001 (JP) 2001-361177

(51) Int. Cl. H05K 1/11; H05K 1/14

(52) U.S. Cl. 361/792

(57) ABSTRACT

A printed wiring board comprises a substrate having a plurality of conductor layers and an insulating layer interposed between the conductor layers and a connecting terminal electrically connecting the conductor layers. The connecting terminal includes a shaft portion penetrating the insulating layer and having a distal end in contact with one of the conductor layers, and a head portion situated on the side opposite from the distal end of the shaft portion and in contact with another one of the conductor layers.

### CROSS-REFERENCE TO RELATED APPLICATIONS

This application is based upon and claims the benefit of priority from the prior Japanese Patent Application No. 2001-361177, filed Nov. 27, 2001, the entire contents of which are incorporated herein by reference.

### BACKGROUND OF THE INVENTION

1. Field of the Invention

The present invention relates to a printed wiring board having conductor layers stacked with insulating layers between them, a circuit module having circuit components mounted on the printed wiring board, and a method for manufacturing the printed wiring board having the electrically connected conductor layers.

2. Description of the Related Art

Multi-layered printed wiring boards that permit circuit components to be mounted thereon with high density are widely used in electronic apparatuses such as portable computers. A multi-layered printed wiring board includes a substrate that has conductor layers and insulating layers stacked alternately. The substrate has through holes. The through holes penetrate the substrate and serve for electrical connection between the conductor layers. The conductor layers to be connected are exposed in the respective inner surfaces of the through holes. Electrically conductive plated layers cover the respective inner surfaces of the through holes. The plated layers are in contact with the conductor layers, so that the conductor layers are connected electrically to one another.

The through holes of the printed wiring board is formed by drilling holes in predetermined positions in the substrate and plating the respective inner surfaces of the holes. Therefore, connecting the conductor layers by using the through holes requires special operations, such as drilling the substrate, plating the inner surface of each drilled hole, etc., thus entailing increased man-hours. In consequence, forming the through holes takes much time and labor, so that the manufacturing cost of the printed wiring board cannot be reasonable.

### BRIEF SUMMARY OF THE INVENTION

An embodiment of the present invention provides a printed wiring board, designed so that conductor layers can be connected electrically to one another.

Another embodiment of the invention provides a circuit module having the printed wiring board.

In order to achieve the first embodiment, a printed wiring board according to the invention comprises a substrate having a plurality of conductor layers and an insulating layer interposed between the conductor layers and a connecting terminal electrically connecting the conductor layers. The connecting terminal includes a shaft portion penetrating the insulating layer and having a distal end in contact with one of the conductor layers, and a head portion situated on the side opposite from the distal end of the shaft portion and in contact with another one of the conductor layers.

According to this configuration, the connecting terminal spans the space between the conductor layers that are divided by the insulating layer, thereby electrically connecting the conductor layers. Thus, the connecting terminal fulfills the same function with a conventional through hole. Accordingly, electrically connecting the conductor layers requires no troublesome, laborious operations such as drilling the substrate, plating the inner surface of each drilled hole, etc. In consequence, the conductor layers can be electrically connected with ease, so that the manufacturing cost of the printed wiring board can be lowered.

Additional features and advantages of the invention will be set forth in the description which follows, and in part will be obvious from the description, or may be learned by practice of the invention. The advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate presently preferred embodiments of the invention, and together with the general description given above and the detailed description of the preferred embodiments given below, serve to explain the principles of the invention.

FIG. 1 is a sectional view of a circuit module according to a first embodiment of the invention, having an IC chip soldered to a multi-layered printed wiring board;

FIG. 2 is a perspective view of a connecting terminal for electrically connecting conductor layers according to the first embodiment of the invention;

FIG. 3 is a sectional view of a double copper-clad laminate used in the first embodiment of the invention;

FIG. 4 is a sectional view of the double copper-clad laminate coated with etching resists according to the first embodiment of the invention;

FIG. 5 is a sectional view of the double copper-clad laminate having first and second internal conductor layers formed thereon according to the first embodiment of the invention;

FIG. 6 is a sectional view of the double copper-clad laminate having the first and second internal conductor layers stabbed with connecting terminals according to the first embodiment of the invention;

FIG. 7 is a sectional view of a laminated substrate having insulating layers and copper leaves alternately stacked on the first and second internal conductor layers of the double copper-clad laminate according to the first embodiment of the invention;

FIG. 8 is a sectional view of the laminated substrate having first and second external conductor layers formed thereon according to the first embodiment of the invention;

FIG. 9 is a sectional view of the laminated substrate having the insulating layers stabbed with connecting terminals according to the first embodiment of the invention;

FIG. 10 is a sectional view of the multi-layered printed wiring board according to the first embodiment of the invention, having the conductor layers connected electrically to one another;

FIG. 11 is a sectional view showing a base for use as an insulating layer stabbed with connecting terminals according to a second embodiment of the invention;

FIG. 12 is a sectional view of a copper-clad laminate having copper leaves put on the base stabbed with the connecting terminals according to the second embodiment of the invention;

FIG. 13 is a sectional view of the copper-clad laminate having first and second internal conductor layers formed thereon according to the second embodiment of the invention;

FIG. 14 is a sectional view showing insulating layers put on the first and second internal conductor layers, individually, and stabbed with connecting terminals according to the second embodiment of the invention;

FIG. 15 is a sectional view of a laminated substrate having copper leaves put individually on the insulating layers stabbed with the connecting terminals according to the second embodiment of the invention; and

FIG. 16 is a sectional view of a multi-layered printed wiring board according to the second embodiment of the invention, having the conductor layers connected electrically to one another.

### DETAILED DESCRIPTION OF THE INVENTION

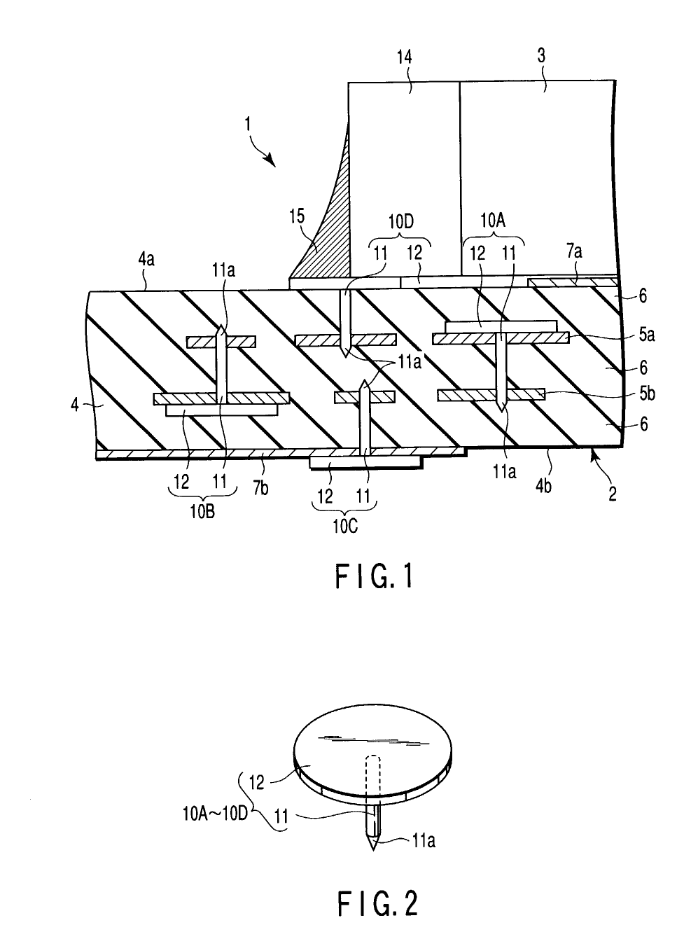

A first embodiment of the present invention will now be described with reference to FIGS. 1 to 10.

FIG. 1 shows a circuit module 1 that is used in an electronic apparatus such as a portable computer. The circuit module 1 comprises a multi-layered printed wiring board 2 and an IC chip 3 for use as a circuit component.

The multi-layered printed wiring board 2 has a substrate 4 that is formed by the build-up process. The substrate 4 includes first and second internal conductor layers 5a and 5b, insulating layers 6, and first and second external conductor layers 7a and 7b.

The first and second internal conductor layers 5a and 5b are composed of a copper leaf each, for example. The internal conductor layers 5a and 5b have a predetermined conductor pattern. The insulating layers 6 are formed of a synthetic resin material such as polyimide or epoxy resin. The insulating layers 6 and the internal conductor layers 5a and 5b are alternately stacked in the thickness direction of the substrate 4. The insulating layers 6 are interposed between the first and second internal conductor layers 5a and 5b and cover them. Thus, the insulating layers 6 constitute an obverse 4a and a reverse 4b of the substrate 4, individually. The first and second external conductor layers 7a and 7b are composed of a copper leaf each, for example. The external conductor layers 7a and 7b have a predetermined conductor pattern. The first external conductor layer 7a is put on the obverse 4a of the substrate 4, and the second external conductor layer 7b on the reverse 4b.

As shown in FIG. 1, connecting terminals 10A, 10B, 10C and 10D are embedded in the substrate 4. The connecting terminals 10A, 10B, 10C and 10D serve for electrical connections between the first and second internal conductor layers 5a and 5b, between the second internal conductor layer 5b and the second external conductor layer 7b, and between the first internal conductor layer 5a and the obverse 4a of the substrate 4. As shown in FIG. 2, each of the connecting terminals has a shaft portion 11 and a head portion 12. The shaft portion 11 and the head portion 12 are formed of a highly conductive metallic material such as copper or a copper alloy.

The shaft portion 11 is a straight pin with a diameter of, e.g., about 0.3 mm and has a pointed distal end 11a. The overall length of the shaft portion 11 is greater than the thickness of the insulating layer 6 that divides the adjacent internal conductor layers 5a and 5b and each of the insulating layers 6 that divide the internal conductor layers 5a and 5b from their corresponding external conductor layers 7a and 7b. The head portion 12 is situated on the end portion of the shaft portion 11 opposite from the distal end 11a. The head portion 12 is in the form of a flat disc that is larger than the shaft portion 11 in diameter. The head portion 12 is coaxial with the shaft portion 11 and juts out in the radial direction of the shaft portion 11.

As shown in FIG. 1, the connecting terminals 10A and 10B electrically connect the first and second internal conductor layers 5a and 5b. The shaft portion 11 of the connecting terminal 10A extends from the first internal conductor layer 5a to the second internal conductor layer 5b. This shaft portion 11 penetrates the first internal conductor layer 5a and the insulating layer 6 that divides the first and second internal conductor layers 5a and 5b in the thickness direction. The distal end 11a of this shaft portion 11 pierces the second internal conductor layer 5b and is covered by the insulating layer 6. Thus, the shaft portion 11 of the connecting terminal 10A spans the space between the first and second internal conductor layers 5a and 5b. The head portion 12 of the connecting terminal 10A overlaps the first internal conductor layer 5a.

The shaft portion 11 of the connecting terminal 10B extends from the second internal conductor layer 5b to the first internal conductor layer 5a. This shaft portion 11 penetrates the second internal conductor layer 5b and the insulating layer 6 that divides the second and first internal conductor layers 5b and 5a in the thickness direction. The distal end 11a of this shaft portion 11 pierces the first internal conductor layer 5a and is covered by the insulating layer 6. Thus, the shaft portion 11 of the connecting terminal 10B spans the space between the first and second internal conductor layers 5a and 5b. The head portion 12 of the connecting terminal 10B overlaps the second internal conductor layer 5b.

The connecting terminal 10C electrically connect the second internal conductor layer 5b and the second external conductor layer 7b. The shaft portion 11 of the connecting terminal 10C extends from the second external conductor layer 7b to the second internal conductor layer 5b. This shaft portion 11 penetrates the second external conductor layer 7b and the insulating layer 6 that divides the second external conductor layer 7b and the second internal conductor layer 5b in the thickness direction. The distal end 11a of this shaft portion 11 pierces the second internal conductor layer 5b and is covered by the insulating layer 6. Thus, the shaft portion 11 of the connecting terminal 10C spans the space between the second external conductor layer 7b and the second internal conductor layer 5b. The head portion 12 of the connecting terminal 10C overlaps the second external conductor layer 7b and is exposed to the outside of the substrate 4.

As shown in FIG. 1, the connecting terminal 10D spans the space between the first internal conductor layer 5a and the obverse 4a of the substrate 4. The shaft portion 11 of the connecting terminal 10D extends from the obverse 4a of the substrate 4 to the first internal conductor layer 5a. This shaft portion 11 penetrates the insulating layer 6 that covers the first internal conductor layer 5a in the thickness direction. The distal end 11a of this shaft portion 11 pierces the first internal conductor layer 5a and is covered by the insulating layer 6. The head portion 12 of the connecting terminal 10D is exposed in the obverse 4a of the substrate 4 and soldered to the obverse 4a.

The IC chip 3 is mounted on the obverse 4a of the substrate 4. The IC chip 3 has a pair of terminal areas 14 (only one of which is shown). The one terminal area 14 is soldered to the head portion 12 of the connecting terminal 10D that is exposed in the obverse 4a of the substrate 4. A fillet 15 is formed partially covering the terminal area 14 and the head portion 12. Thus, the IC chip 3 is fixed to the printed wiring board 2 and connected electrically to the first internal conductor layer 5a through the connecting terminal 10D.

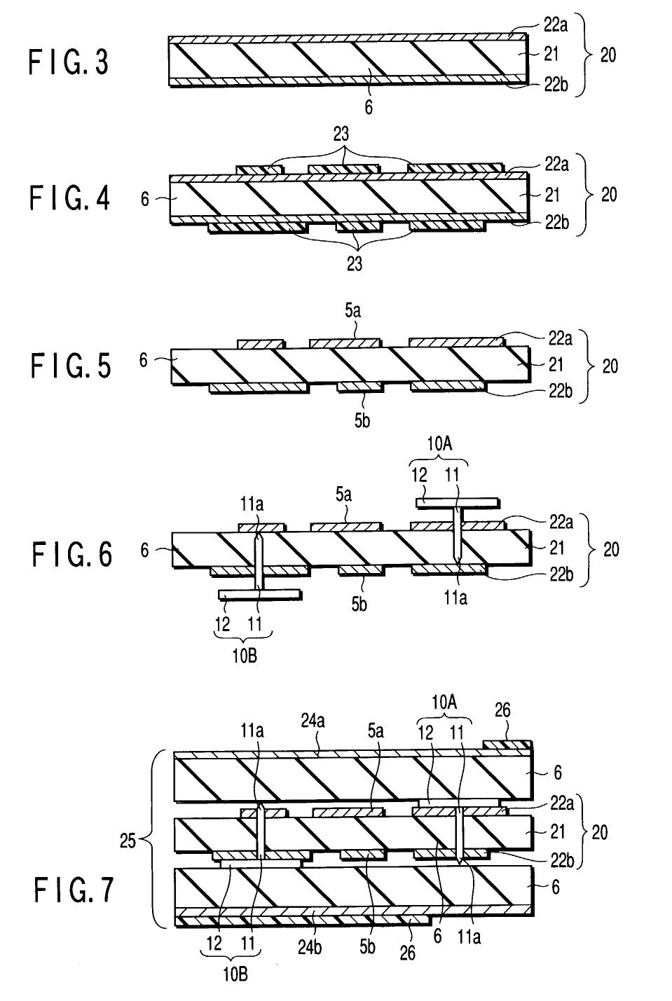

Processes for manufacturing the multi-layered printed wiring board 2 will now be described with reference to FIGS. 3 to 10.

First, a double copper-clad laminate 20 shown in FIG. 3 is prepared. The laminate 20 includes a base 21 that serves as the insulating layer 6 and a pair of copper leaves 22a and 22b. The base 21 maintains a semihardened state such that it allows penetration of the shaft portion 11. The base 21 is sandwiched between the copper leaves 22a and 22b. The copper leaf 22a covers the obverse of the base 21, while the copper leaf 22b covers the reverse of the base.

Then, etching resists 23 such as the ones shown in FIG. 4 are spread on the copper leaves 22a and 22b of the double copper-clad laminate 20, individually. Thereafter, the laminate 20 is etched. In this manner, the first and second internal conductor layers 5a and 5b are formed on the obverse and reverse of the base 21, respectively.

Then, the etching resists 23 are removed to expose the first and second internal conductor layers 5a and 5b, as shown in FIG. 5. Subsequently, the connecting terminals 10A and 10B are located in those positions on the double copper-clad laminate 20 which correspond to the first and second internal conductor layers 5a and 5b to be connected, as shown in FIG. 6. The connecting terminals 10A and 10B are kept in a posture such that the distal ends 11a of their respective shaft portions 11 are directed to the first and second internal conductor layers 5a and 5b, respectively. In this state, the respective distal ends 11a of the shaft portions 11 are stabbed into the base 21 through the first and second internal conductor layers 5a and 5b, individually. Thereupon, the respective shaft portions 11 of the connecting terminals 10A and 10B penetrate the first and second internal conductor layers 5a and 5b, respectively, while their respective head portions 12 face the layers 5a and 5b, respectively.

Then, insulating layers 6 and copper leaves 24a and 24b are stacked on the obverse and reverse of the base 21 that carry the first and second internal conductor layers 5a and 5b thereon, respectively, as shown in FIG. 7. The insulating layers 6 are interposed between the first and second internal conductor layers 5a and 5b and the copper leaves 24a and 24b, and maintain the same semihardened state with the base 21. Thus, the insulating layers 6 cover the first and second internal conductor layers 5a and 5b and the connecting terminals 10, whereupon a laminated substrate 25 such as the one shown in FIG. 7 is completed.

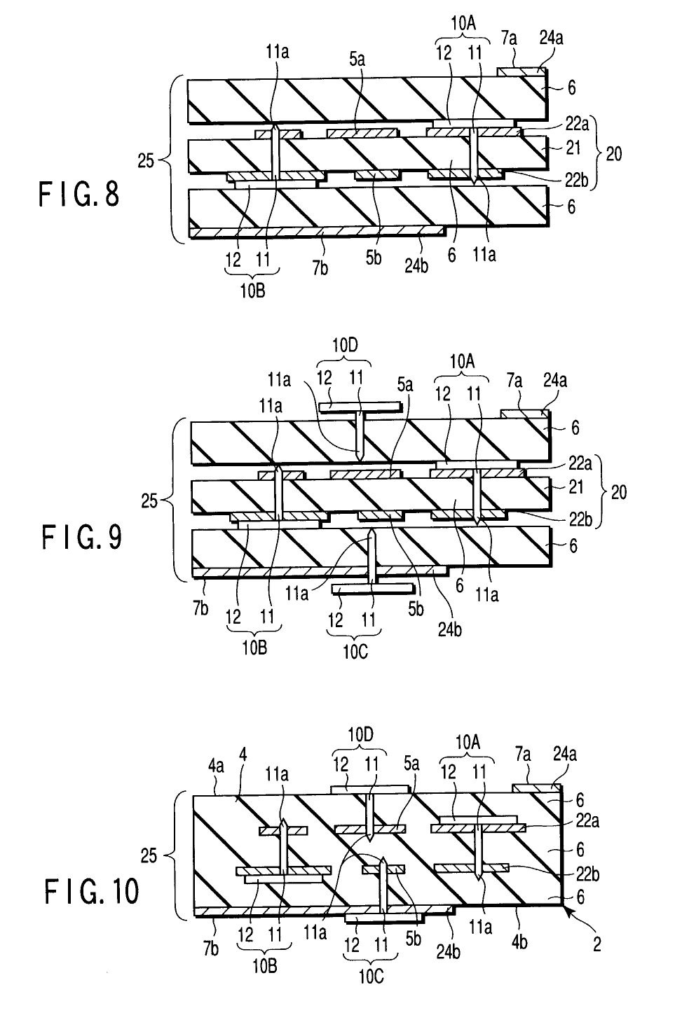

Subsequently, etching resists 26 are spread on the copper leaves 24a and 24b, individually. Thereafter, the laminated substrate 25 is etched. In this manner, the first and second external conductor layers 7a and 7b are formed on the obverse and reverse of the laminated substrate 25, respectively, as shown in FIG. 8.

Then, the etching resists 26 are removed to expose the first and second external conductor layers 7a and 7b. In this state, the connecting terminal 10C is located in that position on the laminated substrate 25 which corresponds to the second internal conductor layer 5b and the second external conductor layer 7b to be connected, as shown in FIG. 9. Likewise, the connecting terminal 10D is located in that position which corresponds to the first internal conductor layer 5a to be connected electrically. The connecting terminal 10C is kept in a posture such that the distal end 11a of its shaft portion 11 is directed to the second external conductor layer 7b, and the distal end 11a of this shaft portion 11 is stabbed into the laminated substrate 25 through the layer 7b. Further, the connecting terminal 10D is kept in a posture such that the distal end 11a of its shaft portion 11 is directed to the first internal conductor layer 5a, and the distal end 11a of this shaft portion 11 is stabbed into the laminated substrate 25.

Then, the laminated substrate 25 is pressurized in its thickness direction by means of a pressing machine. Urged by this pressurization, the distal ends 11a of the respective shaft portions 11 of the connecting terminals 10B and 10D pierce the first internal conductor layer 5a through their corresponding insulating layers 6. Further, the head portion 12 of the connecting terminal 10B overlaps the second internal conductor layer 5b, while the head portion 12 of the connecting terminal 10D overlaps the obverse 4a of the substrate 4.

Likewise, the distal ends 11a of the respective shaft portions 11 of the connecting terminals 10A and 10C pierce the second internal conductor layer 5b through their corresponding insulating layers 6. Further, the head portion 12 of the connecting terminal 10A overlaps the first internal conductor layer 5a, while the head portion 12 of the connecting terminal 10C overlaps the second external conductor layer 7b.

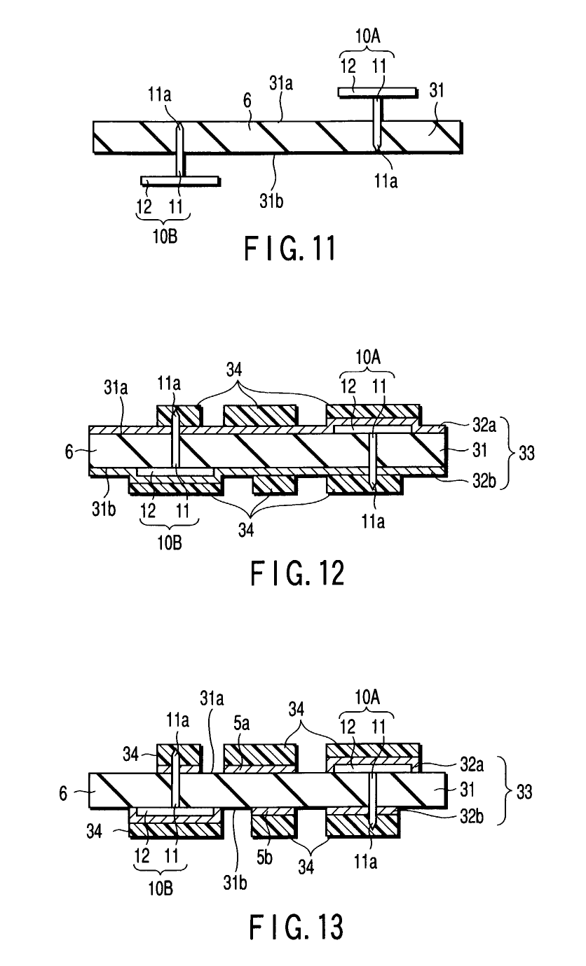

At the same time, the base 21 of the double copper-clad laminate 20 and the two insulating layers 6 are integrated so that the first and second internal conductor layers 5a and 5b are sandwiched between them, whereupon the substrate 4 shown in FIG. 10 is obtained.

In these processes, the connecting terminals 10A, 10B, 10C and 10D are used to make electrical connections between the first and second internal conductor layers 5a and 5b, between the second internal conductor layer 5b and the second external conductor layer 7b, and between the first internal conductor layer 5a and the obverse of the substrate 4. Thereupon, connecting the conductor layers is completed. Finally, surplus odds in the outer peripheral portion of the substrate 4 are trimmed to obtain the printed wiring board 2 with a desired size.

According to the first embodiment of the invention arranged in this manner, the connecting terminals 10A, 10B, 10C and 10D penetrate the insulating layers 6 of the substrate 4 and span the spaces between the conductor layers, thereby electrically connecting the conductor layers in place of conventional through holes. Accordingly, electrically connecting the conductor layers of the printed wiring board 2 requires no troublesome, laborious operations such as drilling the substrate 4, plating the inner surface of each drilled hole, etc. Thus, the conductor layers can be electrically connected with ease, so that the manufacturing cost of the printed wiring board 2 can be lowered.

According to the configuration described above, the head portion 12 of the connecting terminal 10D is exposed in the obverse 4a of the substrate 4 and serves as a pad. Thus, the terminal area 14 of the IC chip 3 can be soldered directly to the head portion 12 of the connecting terminal 10D. Unlike a conventional printed wiring board that uses through holes, therefore, the printed wiring board 2 need not be provided with any dedicated pad for the connection of the terminal area 14 in a position off the through holes.

In consequence, the obverse 4a of the substrate 4 need not secure a space for the pad, so that a lot of circuit components such as IC chips can be mounted highly densely on without increasing the mounting area of the printed wiring board 2.

In some conventional printed wiring boards that use through holes, on the other hand, a conductive lid is used to close the opening end of each through hole. According to this configuration, the lid can be utilized as a pad, so that circuit components can be mounted with high density. This conventional lid is formed of a resin material that is applied to the opening end of each through hole. The upper surface of the resin material is polished level and plated.

However, manufacture of this conventional printed wiring board additionally requires a process for applying the resin material to the opening end of each through hole, a process for polishing the upper surface of the resin material, and a process for plating the upper surface of the resin material. Thus, forming the lid takes much time and labor, so that the efficiency of manufacture of the printed wiring board 2 is poor. Inevitably, moreover, the printed wiring board entails high manufacturing cost.

According to the printed wiring board 2 of the first embodiment, on the other hand, the head portion 12 of the connecting terminal 10D can be exposed in the obverse 4a of the substrate 4 to serve as the pad by only stabbing the shaft portion 11 of the terminal 10D into the insulating layer 6 and pressurizing it. Thus, the pad can be formed more easily than in the conventional case, so that the manufacturing cost of the printed wiring board 2 can be lowered.

The present invention is not limited to the first embodiment described above. FIGS. 11 to 16 show a second embodiment of the invention.

The second embodiment differs from the first embodiment in the process for manufacturing the multi-layered printed wiring board 2. The second embodiment shares other basic configurations of the printed wiring board 2 with the first embodiment. The following is a description of steps of procedure for manufacturing the printed wiring board 2.

As shown in FIG. 11, a flat base 31 is prepared first. The base 31 is formed of a synthetic resin material such as polyimide and has an obverse 31a and a reverse 31b. The base 31 maintains a semihardened state such that it allows penetration of the respective shaft portions 11 of the connecting terminals 10A, 10B, 10C and 10D.

Then, the connecting terminals 10A and 10B are located individually in predetermined positions on the base 31. The connecting terminal 10A is kept in a posture such that the distal end 11a of its shaft portion 11 is directed to the obverse 31a of the base 31, and the distal end 11a is stabbed into the obverse 31a. Likewise, the connecting terminal 10B is kept in a posture such that the distal end 11a of its shaft portion 11 is directed to the reverse 31b of the base 31, and the distal end 11a is stabbed into the reverse 31b. Thereupon, the respective shaft portions 11 of the connecting terminals 10A and 10B penetrate the base 31, while their respective head portions 12 overlap the obverse 31a and the reverse 31b of the base 31, respectively.

Then, copper leaves 32a and 32b are put on the obverse 31a and the reverse 31b of the base 31, respectively, whereupon a copper-clad laminate 33 is formed, as shown in FIG. 12. The copper leaves 32a and 32b cover the respective head portions 12 of the connecting terminals 10A and 10B, respectively. The distal end 11a of the shaft portion 11 of the connecting terminal 10A pierces the copper leaf 32b. The distal end 11a of the shaft portion 11 of the connecting terminal 10B pierces the copper leaf 32a.

Subsequently, etching resists 34 are spread on the copper leaves 32a and 32b, individually. Thereafter, the copper-clad laminate 33 is etched. In this manner, the first and second internal conductor layers 5a and 5b are formed on the obverse 31a and the reverse 31b of the base 31, respectively, as shown in FIG. 13.

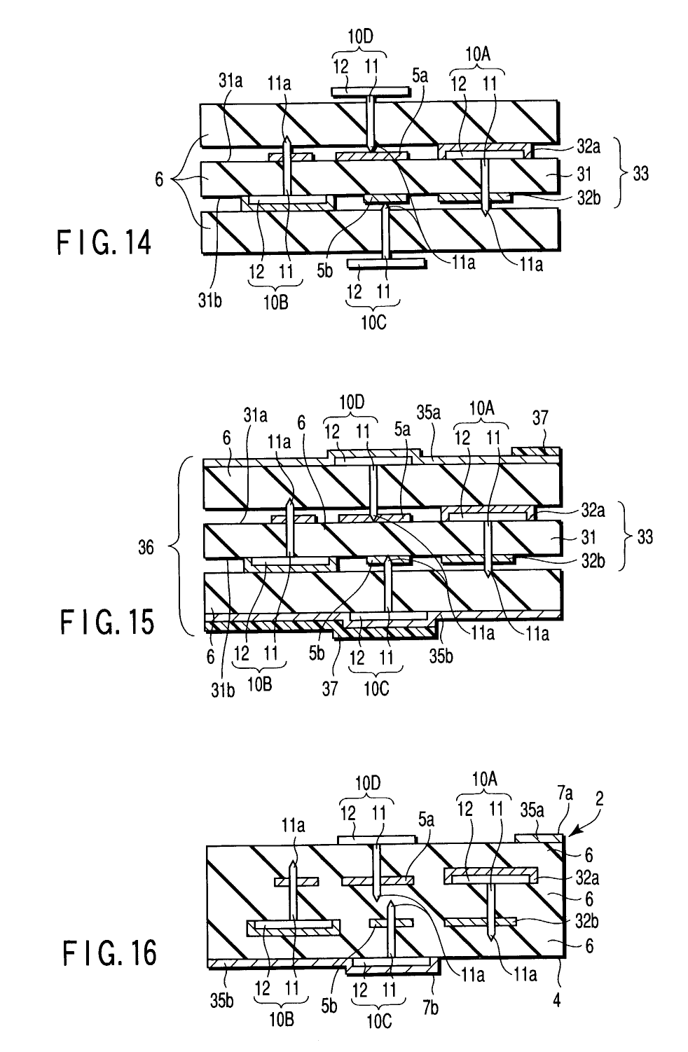

Then, the etching resists 34 are removed to expose the first and second internal conductor layers 5a and 5b. As shown in FIG. 14, moreover, insulating layers 6 are put on the obverse 31a and the reverse 31b of the base 31, individually, and cover the first and second internal conductor layers 5a and 5b. The insulating layers 6 are kept in a semihardened state.

Thereafter, the connecting terminals 10C and 10D are located individually in predetermined positions on the insulating layers 6. These connecting terminals 10C and 10D are kept in a posture such that the distal ends 11a of their shaft portions 11 are directed to their corresponding insulating layers 6, and the distal ends 11a are stabbed into the insulating layers 6. Thereupon, the shaft portions 11 penetrate the insulating layers 6, while the head portions 12 overlap the insulating layers 6.

Then, copper leaves 35a and 35b are put on the insulating layers 6, individually, whereupon a laminated substrate 36 is formed, as shown in FIG. 15. The copper leaf 35a covers the head portion 12 of the connecting terminal 10D. The copper leaf 35b covers the head portion 12 of the connecting terminal 10C. The distal end 11a of the shaft portion 11 of the connecting terminal 10C faces the second internal conductor layer 5b. The distal end 11a of the shaft portion 11 of the connecting terminal 10D faces the first internal conductor layer 5a.

Subsequently, etching resists 37 are spread individually on the copper leaves 35a and 35b of the laminated substrate 36. Thereafter, the laminated substrate 36 is etched. In this manner, the first and second external conductor layers 7a and 7b are formed on the obverse and reverse of the laminated substrate 36, respectively.

Then, the etching resists 37 are removed to expose the first and second external conductor layers 7a and 7b. In this state, the laminated substrate 36 is pressurized in its thickness direction by means of the pressing machine. Urged by this pressurization, the distal end 11a of the shaft portion 11 of the connecting terminal 10C pierces the second internal conductor layer 5b through its corresponding insulating layer 6. Likewise, the shaft portion 11 of the connecting terminal 10D pierces the first internal conductor layer 5a through its corresponding insulating layer 6. At the same time, the base 31 of the copper-clad laminate 33 and the insulating layers 6 are integrated, whereupon the substrate 4 shown in FIG. 16 is obtained.

In these processes, the connecting terminals 10A, 10B, 10C and 10D are used to make electrical connections between the first and second internal conductor layers 5a and 5b, between the second internal conductor layer 5b and the second external conductor layer 7b, and between the first internal conductor layer 5a and the obverse of the substrate 4. Thereupon, connecting the conductor layers is completed.

According to the second embodiment of the invention arranged in this manner, electrically connecting the conductor layers of the printed wiring board 2 requires no troublesome, laborious conventional operations such as drilling the substrate 4, plating the inner surface of each drilled hole, etc. Thus, the conductor layers can be electrically connected with ease.

According to the present invention, the head portion of each connecting terminal is not limited to the shape of a disc. For example, the head portion may be rectangular. Further, the shaft portion is not limited to the shape of a pin, and may alternatively be in the form of a needle that is tapered with distance from the head portion, for example.

Besides, the printed wiring board according to the present invention is not limited to the multi-layered printed wiring board that has the internal conductor layers. For example, it may be a double-sided printed wiring board that has conductor layers only on the obverse and reverse of the substrate.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A printed wiring board comprising:
a substrate having a plurality of conductor layers and an insulating layer interposed between the conductor layers; and
a connecting terminal electrically connecting the conductor layers, the connecting terminal including a shaft portion penetrating the insulating layer and having a distal end in contact with one of the conductor layers, and a head portion situated on the side opposite from the distal end of the shaft portion and in contact with another one of the conductor layers.

2. A printed wiring board according to claim 1, wherein the distal end of said shaft portion is pointed.

3. A printed wiring board according to claim 2, wherein the distal end of said shaft portion pierces the one conductor layer and is covered by the insulating layer.

4. A printed wiring board according to claim 1, wherein the head portion of said connecting terminal juts out in the radial direction of the shaft portion and is put on the other conductor layer.

5. A printed wiring board according to claim 1, wherein said connecting terminal is formed of an electrically conductive metallic material.

6. A printed wiring board according to claim 1, wherein said conductor layer includes an internal conductor layer covered by the insulating layer and an external conductor layer exposed to the outside of the insulating layer, the distal end of the shaft portion of said connecting terminal is in contact with the internal conductor layer, and the head portion of said connecting terminal is in contact with the external conductor layer.

7. Circuit module comprising:
a circuit component having a terminal area; and
a printed wiring board mounted on the circuit component, the printed wiring board including a substrate having an internal conductor layer and a connecting terminal in the substrate and connected electrically to the internal conductor layer, the connecting terminal including a shaft portion piercing the substrate and having a distal end in contact with the internal conductor layer, and a head portion situated on the side opposite from the distal end of the shaft portion, the head portion being exposed to the outside of the substrate and connected electrically to the terminal area of the circuit component.

8. A circuit module according to claim 7, wherein the head portion of said connecting terminal has a diameter larger than that of the shaft portion.

9. A circuit module according to claim 7, wherein the distal end of said shaft portion is pointed so as to pierce the internal conductor layer.

10. A method for manufacturing a printed wiring board having a plurality of conductor layers and an insulating layer interposed between the conductor layers, said method comprising:
forming a substrate by stacking the insulating layer and the conductor layers;
preparing a connecting terminal including a shaft portion having a distal end and a head portion situated on the side opposite from the distal end of the shaft portion and locating the connecting terminal in a predetermined position on the substrate corresponding to the conductor layers; and
pressuring the connecting terminal in the thickness direction of the substrate and stabbing the shaft portion into the insulating layer to bring the distal end of the shaft portion into contact with one of the conductor layers and bring the head portion into contact with another conductor layer.

11. A method for manufacturing a printed wiring board according to claim 10, wherein said insulating layer is kept in a semihardened state when the shaft portion of the connecting terminal is stabbed into the insulating layer.

12. A method for manufacturing a printed wiring board having a plurality of conductor layers stacked with an insulating layer between the layers, said method comprising:
preparing a connecting terminal including a shaft portion having a distal end and a head portion situated on the side opposite from the distal end of the shaft portion;
stabbing the shaft portion of the connecting terminal into a predetermined position in the insulating layer; and
stacking the conductor layers on the insulating layer so that the conductor layers cover the insulating layer and the head portion and the distal end of the shaft portion of the connecting terminal.

13. A method for manufacturing a printed wiring board according to claim 12, wherein said insulating layer and said conductor layers are pressurized in the stacking direction after being stacked.

14. A method for manufacturing a printed wiring board according to claim 12, wherein said insulating layer is kept in a semihardened state when the shaft portion of the connecting terminal is stabbed into the insulating layer.

15. A method for manufacturing a printed wiring board according to claim 12, which further comprising
pressuring the connecting terminal to bring the distal end of the shaft portion into contact with one of the conductor layers and bring the head portion of the connecting terminal into contact with another conductor layer.
